(19) United States
(12) Patent Application Publication
(10) Pub. No.: US 2022/0328515 A1
(43) Pub. Date: Oct. 13, 2022

(54) SEMICONDUCTOR DEVICES

(71) Applicant: Samsung Electronics Co., Ltd., Suwon-si (KR)

(72) Inventors: Jeeyong KIM, Hanam-si (KR); Shin Hum CHO, Hwaseong-si (KR); Joohyung KANG, Suwon-si (KR); Eunsong LEE, Hwaseong-si (KR)

(73) Assignee: Samsung Electronics Co., Ltd., Suwon-si (KR)

(21) Appl. No.: 17/522,175

(22) Filed: Nov. 9, 2021

(30) Foreign Application Priority Data
Apr. 9, 2021 (KR) 10-2021-0046637

(51) Int. Cl. H01L 27/11582; H01L 27/11556

(52) U.S. Cl. CPC H01L 27/11582; H01L 27/11556

(57) ABSTRACT

A semiconductor device includes insulation patterns spaced apart from each other on a substrate in a first direction that is substantially perpendicular to an upper surface of the substrate, gate electrodes spaced apart from each other in the first direction, and a channel extending in the first direction through the insulation patterns and the gate electrodes on the substrate. Each insulation pattern may extend in a second direction that is parallel to the upper surface of the substrate. Each insulation pattern may include boron nitride (BN). Each gate electrode may extend in the second direction between neighboring insulation patterns.

### CROSS-REFERENCE TO RELATED APPLICATIONS

This application claims priority under 35 USC § 119 to Korean Patent Application No. 10-2021-0046637, filed on Apr. 9, 2021 in the Korean Intellectual Property Office (KIPO), the contents of which are herein incorporated by reference in their entirety.

### BACKGROUND

### 1. Field

The inventive concepts relate to semiconductor devices. More particularly, example embodiments of the present inventive concepts relate to vertical memory devices.

### 2. Description of the Related Art

In an electronic system requiring data storage needs a high capacity semiconductor device that may store high capacity data. Thus, the number of stacked insulation patterns and sacrificial layers for forming gate electrodes may increase, and a mold including the insulation patterns and the sacrificial layers may be bent or collapsed in a process of forming the mold.

### SUMMARY

Example embodiments provide a semiconductor device having improved characteristics.

According to example embodiments of the inventive concepts, there is a semiconductor device. The semiconductor device may include insulation patterns spaced apart from each other on a substrate in a first direction that is substantially perpendicular to an upper surface of the substrate, gate electrodes spaced apart from each other in the first direction, and a channel extending in the first direction through the insulation patterns and the gate electrodes on the substrate. Each insulation pattern of the insulation patterns may extend in a second direction that is parallel to the upper surface of the substrate. Each insulation pattern of the insulation patterns may include boron nitride (BN). Each gate electrode of the gate electrodes may extend in the second direction between neighboring insulation patterns of the insulation patterns.

According to example embodiments of the inventive concepts, there is a semiconductor device. The semiconductor device may include gate electrodes spaced apart from each other on a substrate in a first direction that is substantially perpendicular to an upper surface of the substrate, insulation patterns that are each between neighboring gate electrodes of the gate electrodes, and a channel extending in the first direction through the insulation patterns and the gate electrodes on the substrate. Each gate electrode of the gate electrodes may extend in a second direction that is parallel to the upper surface of the substrate. The insulation patterns may include an insulating material having a dielectric constant less than a dielectric constant of silicon oxide. A thickness ratio in the first direction of each insulation pattern of the insulation patterns to each gate electrode of the gate electrodes may be equal to or less than about 90%.

According to example embodiments of the inventive concepts, there is a semiconductor device. The semiconductor device may include a lower circuit pattern on a substrate, a common source plate (CSP) on the lower circuit pattern, insulation patterns spaced apart from each other on the CSP in a first direction that is substantially perpendicular to an upper surface of the substrate, gate electrodes spaced apart from each other in the first direction, and a memory channel structure extending through the insulation patterns and the gate electrodes on the CSP and connected to the CSP. Each insulation pattern of the insulation patterns may extend in a second direction that is parallel to the upper surface of the substrate. Each insulation pattern of the insulation patterns may include boron nitride (BN). Each gate electrode of the gate electrodes may extend in the second direction between neighboring insulation patterns of the insulation patterns. The memory channel structure may include a channel extending in the first direction, and a charge storage structure surrounding an outer sidewall of the channel.

In a method of manufacturing a semiconductor device according to example embodiments, a mold may include an insulation layer having a small thickness in a vertical direction, and thus a height of the mold may be lowered. Accordingly, the mold might not be bent and/or collapsed in a manufacturing process of the semiconductor device.

### BRIEF DESCRIPTION OF THE DRAWINGS

FIG. 1 is a schematic diagram illustrating an electronic system including a semiconductor device in accordance with example embodiments.

FIG. 2 is a schematic perspective view illustrating an electronic system including a semiconductor device in accordance with example embodiments.

FIGS. 3 and 4 are schematic cross-sectional views illustrating semiconductor packages each of which may include a semiconductor device in accordance with example embodiments.

FIGS. 5, 6, 7, 8, 9, 10, 11, 12, 13, and 14 are plan views and cross-sectional views illustrating a method of manufacturing a semiconductor device in accordance with example embodiments.

### DETAILED DESCRIPTION

The above and other aspects and features of the semiconductor devices and the methods of manufacturing the same in accordance with example embodiments will become readily understood from detail descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

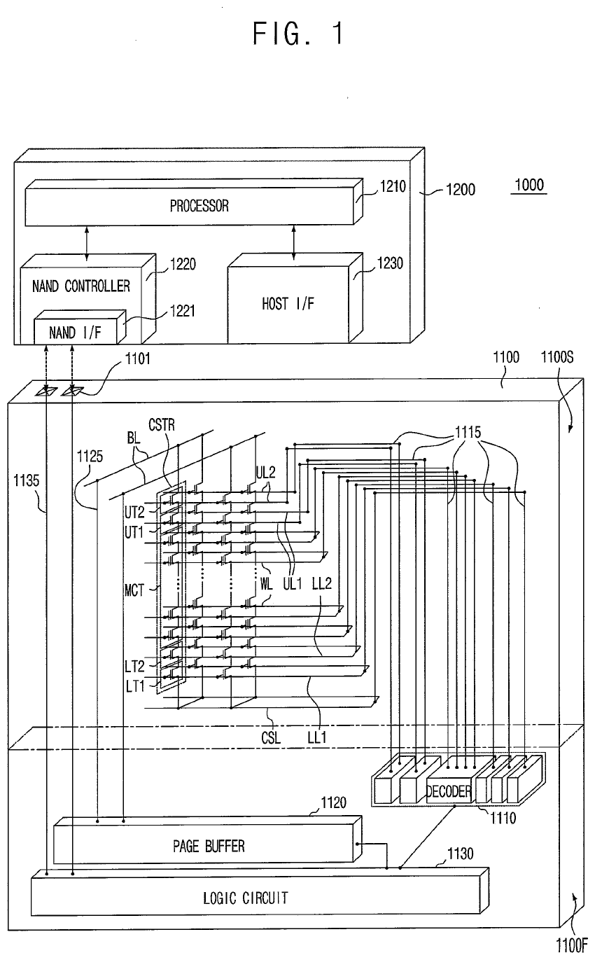

FIG. 1 is a schematic diagram illustrating an electronic system including a semiconductor device in accordance with example embodiments.

Referring to FIG. 1, an electronic system 1000 may include a semiconductor device 1100 and a controller 1200 electrically connected to the semiconductor device 1100. The electronic system 1000 may be a storage device including one or a plurality of semiconductor devices 1100 or an electronic device including a storage device. For example, the electronic system 1000 may be a solid state drive (SSD) device, a universal serial bus (USB), a computing system, a medical device, or a communication device that may include one or a plurality of semiconductor devices 1100. The semiconductor device 1100 may be, may include, and/or may be included in a semiconductor device, semiconductor storage device, or the like according to any of the example embodiments.

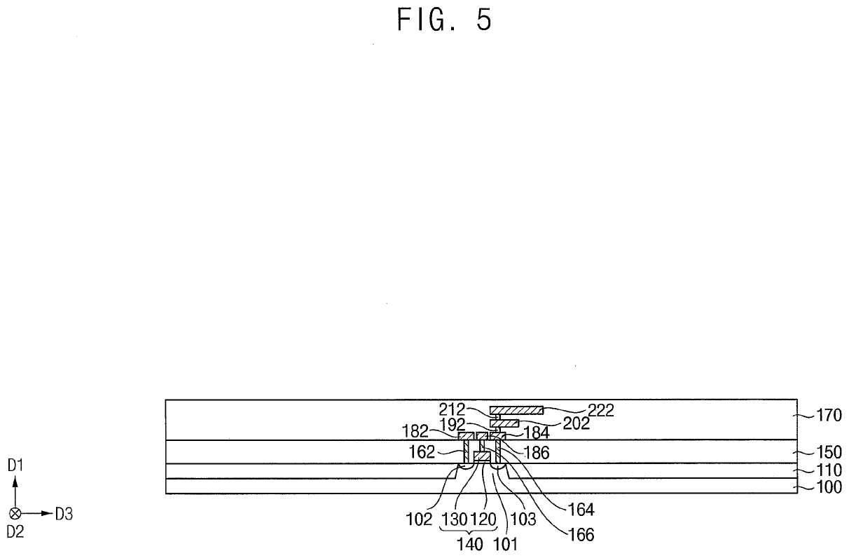

The semiconductor device 1100 may be a non-volatile memory device, for example, a NAND flash memory device that will be illustrated with reference to FIGS. 5 to 14. The semiconductor device 1100 may include a first structure 1100F and a second structure 1100S on the first structure 1100F. In the drawing, the first structure 1100F is disposed under the second structure 1100S, however, the inventive concepts might not be limited thereto, and may be disposed beside or on the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second upper gate lines UL1 and UL2, first and second lower gate lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of the lower transistors LT1 and LT2 and the number of the upper transistors UT1 and UT2 may be varied in accordance with example embodiments.

In example embodiments, the upper transistors UT1 and UT2 may include string selection transistors, and the lower transistors LT1 and LT2 may include ground selection transistors. The lower gate lines LL1 and LL2 may be gate electrodes of the lower transistors LT1 and LT2, respectively. The word lines WL may be gate electrodes of the memory cell transistors MCT, respectively, and the upper gate lines UL1 and UL2 may be gate electrodes of the upper transistors UT1 and UT2, respectively.

In example embodiments, the lower transistors LT1 and LT2 may include a lower erase control transistor LT1 and a ground selection transistor LT2 that may be connected with each other in serial. The upper transistors UT1 and UT2 may include a string selection transistor UT1 and an upper erase control transistor UT2. At least one of the lower erase control transistor LT1 or the upper erase control transistor UT2 may be used in an erase operation for erasing data stored in the memory cell transistors MCT through gate induced drain leakage (GIDL) phenomenon.

The common source line CSL, the first and second lower gate lines LL1 and LL2, the word lines WL, and the first and second upper gate lines UL1 and UL2 may be electrically connected to the decoder circuit 1110 through first connection wirings 1115 extending to the second structure 1100S in the first structure 1100F. The bit lines BL may be electrically connected to the page buffer 1120 through second connection wirings 1125 extending to the second structure 1100S in the first structure 1100F.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending to the second structure 1100S in the first structure 1100F. The controller 1200 may be electrically connected to the semiconductor device 1100 through the input/output pad 1101. Thus, the controller 1200 may be electrically connected to a semiconductor device, semiconductor storage device, or the like that may be included in and/or at least partially comprise the semiconductor device 1100, through the input/output pad 1101. The controller 1200 may be configured to control the semiconductor device 1100 (e.g., via communication with the semiconductor device 1100 via the input/output pad 1101).

The controller 1200 may include a processor 1210, a NAND controller 1220, and a host interface 1230. The electronic system 1000 may include a plurality of semiconductor devices 1100, and in some example embodiments, the controller 1200 may control the plurality of semiconductor devices 1100.

The processor 1210 may control operations of the electronic system 1000 including the controller 1200. The processor 1210 may be operated by firmware, and may control the NAND controller 1220 to access the semiconductor device 1100. The NAND controller 1220 may include a NAND interface 1221 for communicating with the semiconductor device 1100. Through the NAND interface 1221, control command for controlling the semiconductor device 1100, data to be written in the memory cell transistors MCT of the semiconductor device 1100, data to be read from the memory cell transistors MCT of the semiconductor device 1100, etc., may be transferred. The host interface 1230 may provide communication between the electronic system 1000 and an outside host. When control command is received from the outside host through the host interface 1230, the processor 1210 may control the semiconductor device 1100 in response to the control command.

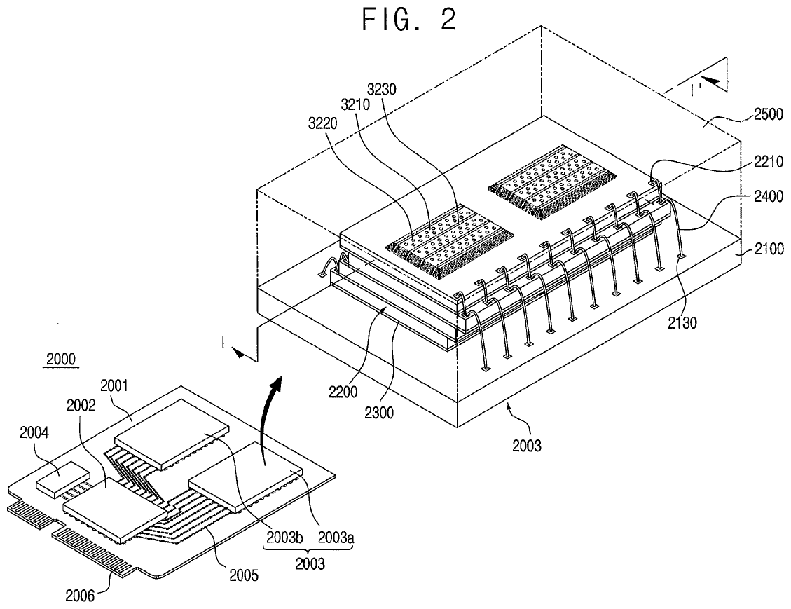

FIG. 2 is a schematic perspective view illustrating an electronic system including a semiconductor device in accordance with example embodiments.

Referring to FIG. 2, an electronic system 2000 may include a main substrate 2001, a controller 2002 mounted on the main substrate 2001, at least one semiconductor package 2003, and a dynamic random access memory (DRAM) device 2004. The semiconductor package 2003 and the DRAM device 2004 may be connected with each other by wiring patterns 2005 on the main substrate 2001.

The main substrate 2001 may include a connector 2006 having a plurality of pins connected to an outside host. The number and layout of the plurality pins in the connector 2006 may be changed depending on communication interface between the electronic system 2000 and the outside host. In example embodiments, the electronic system 2000 may communicate with the outside host according to one of a USB, peripheral component interconnect express (PCI-Express), serial advanced technology attachment (SATA), M-Phy for universal flash storage (UFS), etc. In example embodiments, the electronic system 2000 may be operated by power source provided from the outside host through the connector 2006. The electronic system 2000 may further include power management integrated circuit (PMIC) for distributing the power source provided from the outside host to the controller 2002 and the semiconductor package 2003.

The controller 2002 may write data in the semiconductor package 2003 or read data from the semiconductor package 2003, and may enhance the operation speed of the electronic system 2000.

The DRAM device 2004 may be a buffer memory for reducing the speed difference between the semiconductor package 2003 for storing data and the outside host. The DRAM device 2004 included in the electronic system 2000 may serve as a cache memory, and may provide a space for temporarily storing data during the control operation for the semiconductor package 2003. If the electronic system 2000 includes the DRAM device 2004, the controller 2002 may further include a DRAM controller for controlling the DRAM device 2004 in addition to the NAND controller for controlling the semiconductor package 2003.

The semiconductor package 2003 may include first and second semiconductor packages 2003a and 2003b spaced apart from each other (e.g., isolated from direct contact with each other). The first and second semiconductor packages 2003a and 2003b may be semiconductor packages each of which may include a plurality of semiconductor chips 2200. Each of the first and second semiconductor packages 2003a and 2003b may include a package substrate 2100, the semiconductor chips 2200, bonding layers 2300 disposed under the semiconductor chips 2200, a connection structure 2400 for electrically connecting the semiconductor chips 2200 and the package substrate 2100, and a mold layer 2500 covering the semiconductor chips 2200 and the connection structure 2400 on the package substrate 2100.

The package substrate 2100 may be a printed circuit board (PCB) covering package upper pads 2130. Each semiconductor chip 2200 may include an input/output pad 2210. The input/output pad 2210 may correspond to the input/output pad 1101 of FIG. 1. Each semiconductor chip 2200 may include gate electrode structures 3210, memory channel structures 3220 extending through the gate electrode structures 3210, and division structures 3230 for dividing the gate electrode structures 3210. Each semiconductor chip 2200 may include a semiconductor device that will be illustrated with reference to FIGS. 29 to 38.

In example embodiments, the connection structure 2400 may be a bonding wire for electrically connecting the input/output pad 2210 and the package upper pads 2130. Thus, in the first and second semiconductor packages 2003a and 2003b, the semiconductor chips 2200 may be electrically connected with each other by a bonding wire method, and may be electrically connected to the package upper pads 2130 of the package substrate 2100. Alternatively, in each of the first and second semiconductor packages 2003a and 2003b, the semiconductor chips 2200 may be electrically connected with each other by a connection structure including through silicon via (TSV), instead of the connection structure 2400 of the bonding wire method.

In example embodiments, the controller 2002 and the semiconductor chips 2200 may be included in one package. In example embodiments, the controller 2002 and the semiconductor chips 2200 may be mounted on an interposer substrate different from the main substrate 2001, and the controller 2002 and the semiconductor chips 2200 may be connected with each other by a wiring on the interposer substrate.

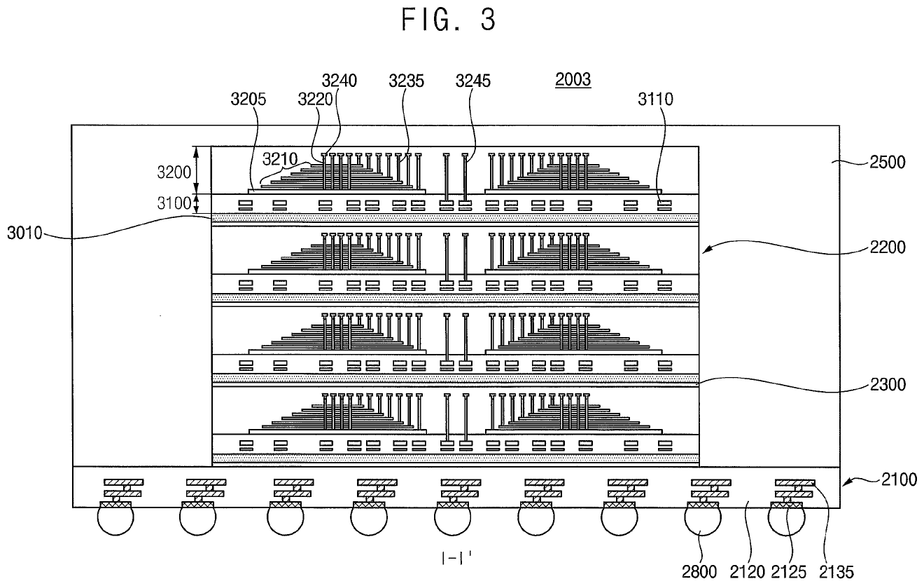

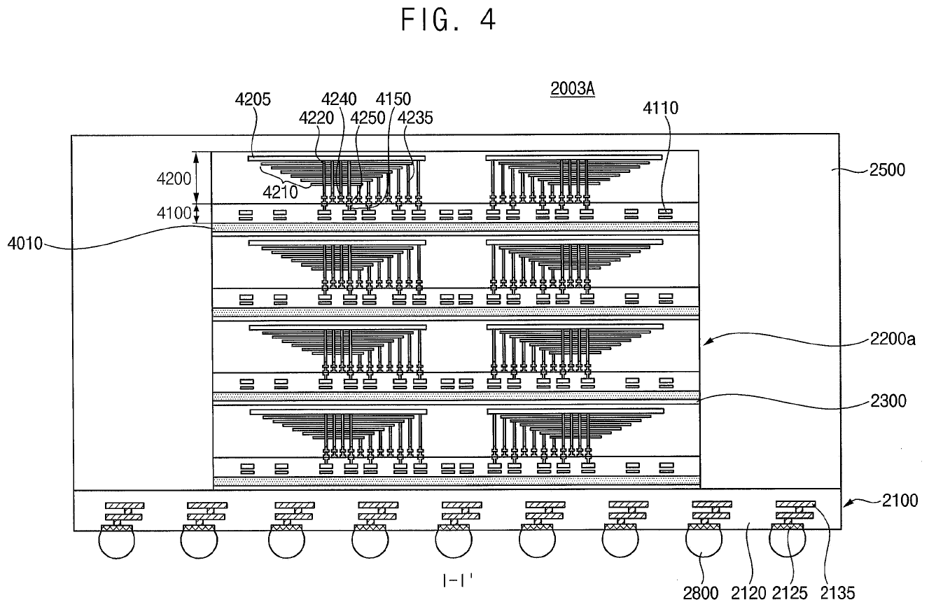

FIGS. 3 and 4 are schematic cross-sectional views illustrating semiconductor packages each of which may include a semiconductor device in accordance with example embodiments. FIGS. 3 and 4 illustrate example embodiments of the semiconductor package 2003 shown in FIG. 2, and show a cross-section taken along a line I-I′ of the semiconductor package 2003 in FIG. 2.

Referring to FIG. 3, in the semiconductor package 2003, the package substrate 2100 may be a PCB. The package substrate 2100 may include a substrate body part 2120, upper pads 2130 (refer to FIG. 2) on an upper surface of the substrate body part 2120, lower pads 2125 on a lower surface of the substrate body part 2120 or exposed through the lower surface of the substrate body part 2120, and inner wirings 2135 for electrically connecting the upper pads 2130 and the lower pads 2125 in an inside of the substrate body part 2120. The upper pads 2130 may be electrically connected to the connection structures 2400. The lower pads 2125 may be connected to wiring patterns 2005 of the main substrate 2001 in the electronic system 2000 through conductive connection parts 2800, as in FIG. 2.

Each semiconductor chip 2200 may include a semiconductor substrate 3010, and a first structure 3100 and a second structure 3200 sequentially stacked on the semiconductor substrate 3010. The first structure 3100 may include a peripheral circuit region in which peripheral circuit wirings 3110 may be formed. The second structure 3200 may include a common source line 3205, a gate electrode structure 3210 on the common source line 3205, memory channel structures 3220 and division structures 3230 (refer to FIG. 2) extending through the gate electrode structure 3210, bit lines 3240 electrically connected to the memory channel structures 3220, and gate connection wirings 3235 electrically connected to the word lines WL of the gate electrode structure 3210 (refer to FIG. 1).

Each semiconductor chip 2200 may include a through wiring 3245 being electrically connected to the peripheral circuit wirings 3110 of the first structure 3100 and extending in the second structure 3200. The through wiring 3245 may be disposed at an outside of the gate electrode structure 3210, and some through wirings 3245 may extend through the gate electrode structure 3210. Each semiconductor chip 2200 may further include the input/output pad 2210 (refer to FIG. 2) electrically connected to the peripheral circuit wirings 3110 of the first structure 3100.

Referring to FIG. 4, in a semiconductor package 2003A, each semiconductor chip 2200a may include a semiconductor substrate 4010, a first structure 4100 on the semiconductor substrate 4010, and a second structure 4200 on and bonded with the first structure 4100 by a wafer bonding method.

The first structure 4100 may include a peripheral circuit region in which a peripheral circuit wiring 4110 and first bonding structures 4150 may be formed. The second structure 4200 may include a common source line 4205, a gate electrode structure 4210 between the common source line 4205 and the first structure 4100, memory channel structures 4220 and the division structure 3230 (refer to FIG. 2) extending through the gate electrode structure 4210, and second bonding structures 4250 electrically connected to the memory channel structures 4220 and the word lines WL (refer to FIG. 1) of the gate electrode structure 4210. For example, the second bonding structures 4250 may be electrically connected to the memory channel structures 4220 and the word lines WL (refer to FIG. 1) through the bit lines 4240 electrically connected to the memory channel structures 4220 and the gate connection wirings 4235 electrically connected to the word lines WL (refer to FIG. 1), respectively. The first bonding structures 4150 of the first structure 4100 and the second bonding structures 4250 of the second structure 4200 may contact each other to be bonded with each other. The first bonding structures 4150 and the second bonding structures 4250 may include, e.g., copper.

Each semiconductor chip 2200a may further include the input/output pad 2210 (refer to FIG. 2) electrically connected to the peripheral circuit wirings 4110 of the first structure 4100.

The semiconductor chips 2200 of FIG. 3 and the semiconductor chips 2200a of FIG. 4 may be electrically connected with each other by the connection structures 2400 in a bonding wire method. However, in example embodiments, semiconductor chips such as the semiconductor chips 2200 of FIG. 3 and the semiconductor chips 2200a of FIG. 4 in the same semiconductor package may be electrically connected with each other by a connection structure including a TSV.

FIGS. 5, 6, 7, 8, 9, 10, 11, 12, 13, and 14 are cross-sectional views illustrating a method of manufacturing a semiconductor device in accordance with example embodiments.

This semiconductor device may correspond to the second structure 1100S of FIG. 1, the semiconductor chips 2200 of FIG. 2, and the second structure 3200 of FIG. 3.

Hereinafter, in the specification (but not necessarily in the claims) a direction perpendicular or substantially perpendicular to an upper surface of a substrate may be defined as a first direction D1, and two directions parallel or substantially parallel to the upper surface of the substrate and crossing each other may be defined as second and third directions D2 and D3, respectively. In example embodiments, the second and third directions D2 and D3 may be perpendicular or substantially perpendicular to each other.

Referring to FIG. 5, a lower circuit pattern may be formed on a substrate 100, and first and second insulating interlayers 150 and 170 including an oxide, e.g., silicon oxide may be sequentially formed on the substrate 100 to cover the lower circuit pattern.

The substrate 100 may include silicon, germanium, silicon-germanium or a III-V compound such as GaP, GaAs, GaSb, etc. In some example embodiments, the substrate 100 may be a silicon-on-insulator (SOI) substrate or a germanium-on-insulator (GOI) substrate.

The substrate 100 may include a field region on which an isolation pattern 110 is formed, and an active region on which no isolation pattern 110 is formed. The isolation pattern 110 may include an oxide, e.g., silicon oxide.

In example embodiments, the vertical memory device may have a cell over periphery (COP) structure. That is, the lower circuit pattern may be formed on the substrate 100, and memory cells, upper contact plugs, and an upper circuit pattern may be formed over the lower circuit pattern. The lower circuit pattern may include, e.g., transistors, lower contact plugs, lower wirings, lower vias, etc.

The transistor may include a lower gate structure 140 on the substrate 100 and first and second impurity regions 102 and 103 serving as source/drains at upper portions of the active region 101 adjacent to the lower gate structure 140. The lower gate structure 140 may include a lower gate insulation pattern 120 and a lower gate electrode 130 sequentially stacked on the substrate 100.

The first insulating interlayer 150 may be formed on the substrate 100 to cover the transistor. First and second lower contact plugs 162 and 164 may extend through the first insulating interlayer 150 to contact the first and second impurity regions 102 and, respectively, and a third lower contact plug 166 may extend through the first insulating interlayer 150 to contact the lower gate electrode 130.

First to third lower wirings 182, 184 and 186 may be formed on the first insulating interlayer 150 to contact upper surfaces of the first to third lower contact plugs 162, 164 and 166, respectively. A first lower via 192, a fourth lower wiring 202, a second lower via 212 and a fifth lower wiring 222 may be sequentially stacked on the second lower wiring 184.

The second insulating interlayer 170 may be formed on the first insulating interlayer 150 to cover the first to fifth lower wirings 182, 184, 186, 202 and 222 and the first and second lower vias 192 and 212. The second insulating interlayer 170 may be merged with the first insulating interlayer 150 thereunder.

The elements of the lower circuit pattern may be formed by a patterning process or a damascene process.

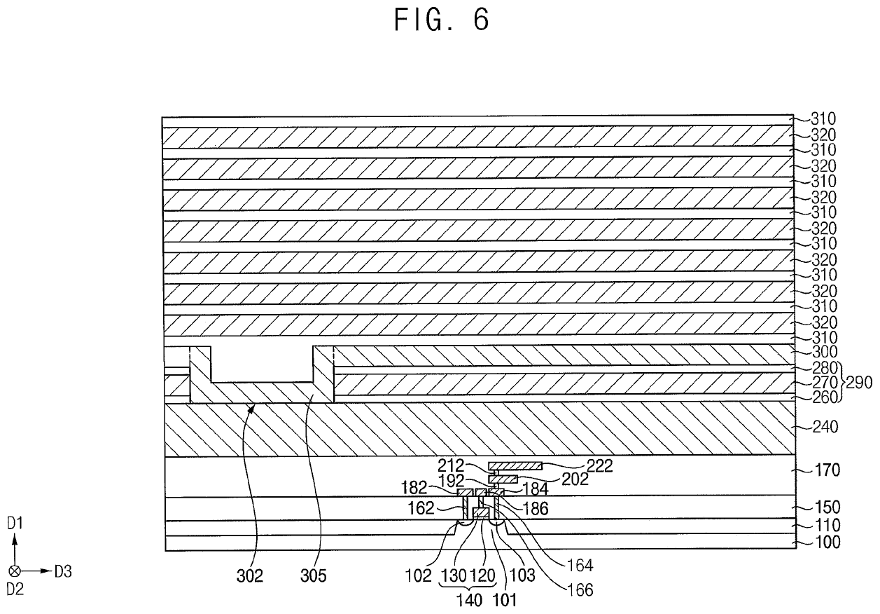

Referring to FIG. 6, a common source plate (CSP) 240 and a sacrificial layer structure 290 may be sequentially formed on the second insulating interlayer 170 (e.g., on the lower circuit pattern). After forming a first opening 302 exposing an upper surface of the CSP 240 by partially removing the sacrificial layer structure 290, a support layer 300 may be formed on an upper surface of the sacrificial layer structure 290 and the exposed upper surface of the CSP 240.

The CSP 240 may include, e.g., polysilicon doped with n-type impurities. Alternatively, the CSP 240 may include a metal silicide layer and a polysilicon layer doped with n-type impurities sequentially stacked. The metal silicide layer may include, e.g., tungsten silicide.

The sacrificial layer structure 290 may include first to third sacrificial layers 260, 270 and 280 sequentially stacked. Each of the first and third sacrificial layers 260 and 280 may include an oxide, e.g., silicon oxide, and the second sacrificial layer 270 may include a nitride, e.g., silicon nitride.

The support layer 300 may include a material having an etching selectivity with respect to the first to third sacrificial layers 260, 270 and 280, e.g., doped or undoped polysilicon. In some example embodiments, the support layer 300 may be formed by depositing doped or undoped amorphous silicon, and by performing a heat treatment or by being crystallized through heat generated during deposition processes for other structures to include doped or undoped polysilicon.

The support layer 300 may have a uniform thickness, and thus a first recess may be formed on a portion of the support layer 300 in the first opening 302. Hereinafter, the portion of the support layer 300 in the first opening 302 may be referred to as a support pattern 305.

The insulation layer 310 and a fourth sacrificial layer 320 may be alternately and repeatedly formed on the support layer 300 and the support pattern 305, and thus a mold layer including the insulation layers 310 and the fourth sacrificial layers 320 may be formed.

The insulation layer 310 and the fourth sacrificial layer 320 may be formed by, e.g., a chemical vapor deposition (CVD) process or an atomic layer deposition (ALD). In some example embodiments, the CVD process may include, e.g., a plasma enhanced chemical vapor deposition (PECVD) process.

The insulation layer 310 may include, e.g., an insulating material having a sufficiently small dielectric constant (k). In example embodiments, the insulation layer 310 may include, e.g., amorphous boron nitride (BN) and/or crystalline boron nitride. In some example embodiments, the insulation layer 310 may be formed by a CVD process and include amorphous boron nitride, and a dielectric constant of the insulation layer 310 may be less than about 1.8 (e.g., greater than 0 and less than about 1.8, greater than about 0.001 and less than about 1.8, etc.). In other example embodiments, the insulation layer 310 may be formed by a CVD process and include amorphous boron nitride and crystalline boron nitride, and a dielectric constant of the insulation layer 310 may be equal to or more than about 1.8 and less than about 3. In still other example embodiments, the insulation layer 310 may be formed by an ALD process and include crystalline boron nitride, and a dielectric constant of the insulation layer 310 may be equal to or more than about 3 and less than about 3.3. In some example embodiments, each insulation pattern 315 may include boron nitride, and each insulation pattern 315 may have a dielectric constant of less than about 3.3.

The fourth sacrificial layer 320 may include a material having an etching selectivity with respect to the insulation layer 310 including, e.g., a nitride such as silicon nitride. The fourth sacrificial layer 320 may include a material having an etching selectivity with respect to the second insulating interlayer layer 170 including, e.g., a nitride such as silicon nitride.

A patterning process using a photoresist pattern as an etching mask may be performed on the insulation layer 310 and the fourth sacrificial layer 320, and a trimming process for reducing an area of the photoresist pattern may be performed. The patterning process and the trimming process may be alternately and repeatedly performed to form a mold having a plurality of step layers each including the fourth sacrificial layer 320 and the insulation layer 310 sequentially stacked on the substrate 100.

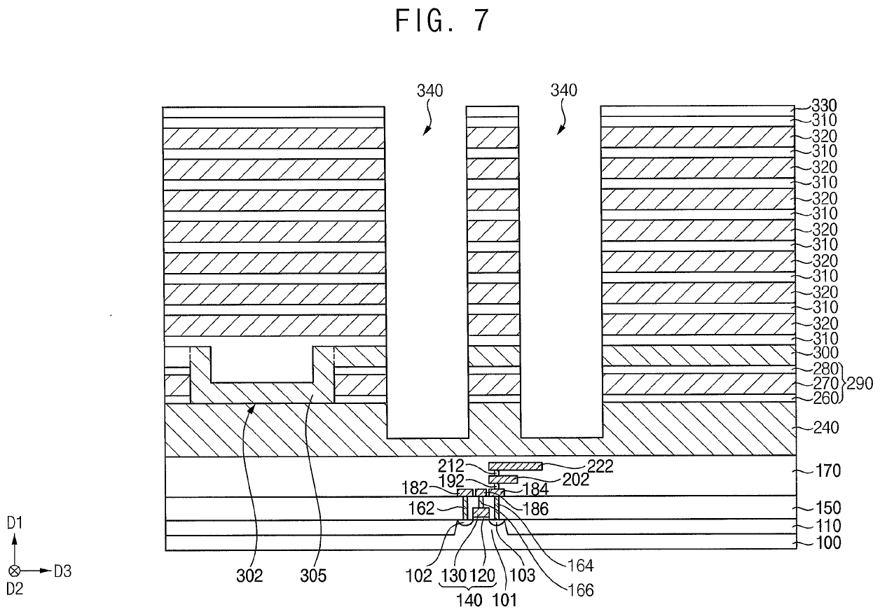

Referring to FIG. 7, a third insulating interlayer 330 may be formed on the substrate 100 to cover the mold, and a channel hole 340 may be formed through the third insulating interlayer 330 and the mold to expose an upper surface of the CSP 240 by, e.g., a dry etching process.

In example embodiments, the dry etching process may be performed until the upper surface of the CSP 240 may be exposed, and an upper portion of the CSP 240 may be further removed in the dry etching process. In example embodiments, a plurality of channel holes 340 may be formed in each of the second and third directions D2 and D3, and thus a channel hole array may be defined.

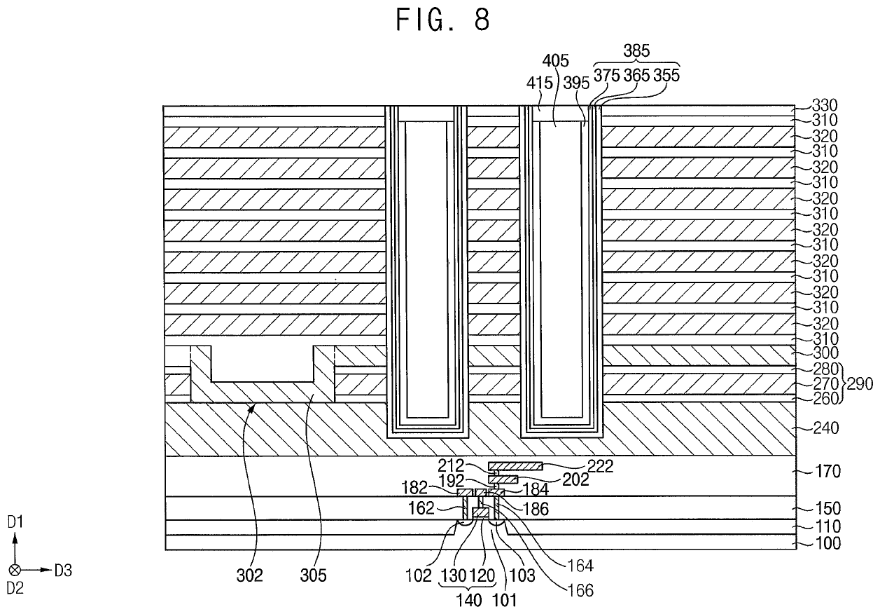

Referring to FIG. 8, a charge storage structure layer and a channel layer may be sequentially formed on a sidewall of the channel hole 340, the exposed upper surface of the CSP 240, and an upper surface of the third insulating interlayer 330, and a filling layer may be formed on the channel layer to fill the channel hole 340.

A charge storage structure layer may include a first blocking layer, a charge storage layer and a tunnel insulation layer sequentially stacked. The first blocking layer and the tunnel insulation layer may include an oxide, e.g., silicon oxide, the charge storage layer may include a nitride, e.g., silicon nitride, the channel layer may include, e.g., polysilicon undoped with impurities or lightly doped with impurities, and the filling layer may include, e.g., an oxide such as silicon oxide.

The filling layer, the channel layer and the charge storage structure layer may be planarized until the upper surface of the third insulating interlayer 330 is exposed to form a filling pattern 405, a channel 395 and a charge storage structure 385, respectively, in each of the channel holes 340. The charge storage structure 385 may include a first blocking pattern 355, a charge storage pattern 365 and a tunnel insulation pattern 375 sequentially stacked from the sidewall and a bottom of the channel hole 340.

In example embodiments, the filling pattern 405 may have a pillar shape extending in the first direction D1, and each of the channel 395 and the charge storage structure 385 may have a cup-like shape.

As the channel hole 340 in which the channel 395 is formed may define the channel hole array, the channel 395 in the channel hole 340 may also define a channel array.

Upper portions of the filling pattern 405 and the channel 395 may be removed to form a second recess, a pad layer may be formed on the filling pattern 405, the channel 395, the charge storage structure 385 and the third insulating interlayer 330 to fill the second recess, and the pad layer may be planarized until the upper surface of the third insulating interlayer 330 is exposed to form a pad 415 contacting an upper inner sidewall of the charge storage structure 385. The pad 415 may include, e.g., polysilicon doped with or undoped with impurities.

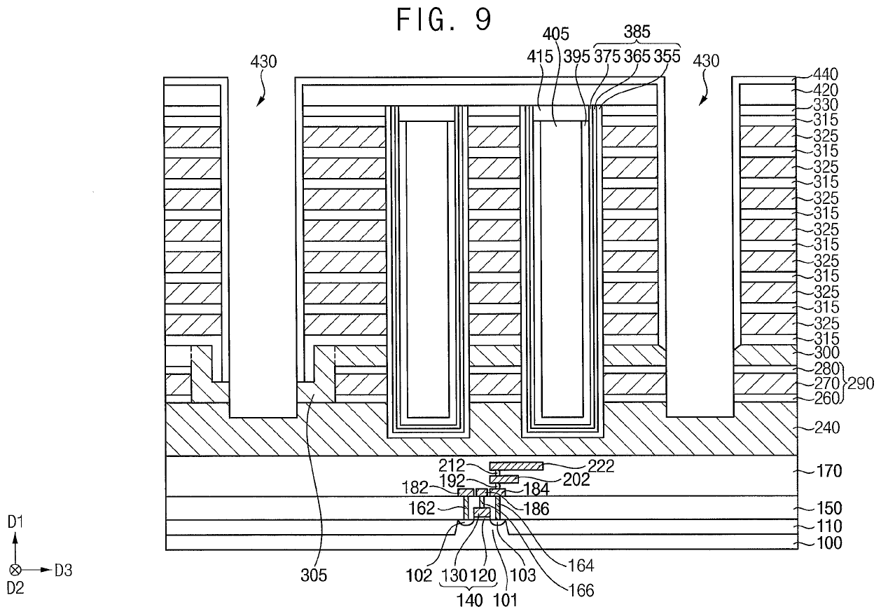

Referring to FIG. 9, a fourth insulating interlayer 420 may be formed on the third insulating interlayer 330, the charge storage structure 385 and the pad 415, and a second opening 430 may be formed through the third and fourth insulating interlayers 330 and 420 and the mold by a dry etching process.

In example embodiments, the dry etching process may be performed until an upper surface of the support layer 300 or an upper surface of the support pattern 305 is exposed, and an upper portion of the support layer 300 or an upper portion of the support pattern 305 may be also removed during the dry etching process. As the second opening 430 is formed, the insulation layers 310 and the fourth sacrificial layers 320 of the mold may be exposed.

In example embodiments, the second opening 430 may extend in the second direction D2, and a plurality of second openings 430 may be formed in the third direction D3. As the second opening 430 is formed, the insulation layer 310 may be divided into insulation patterns 315 each of which may extend in the second direction D2, and the fourth sacrificial layer 320 may be divided into fourth sacrificial patterns 325 each of which may extend in the second direction D2.

A spacer layer may be formed on a sidewall of the second opening 430, the exposed upper surface of the second opening 430, an upper surface of the fourth insulating interlayer 420, and may be anisotropically etched to remove portions of the spacer layer on the upper surfaces of the support layer 300 and the support pattern 305, so that a spacer 440 may be formed and that the upper surfaces of the support layer 300 and the support pattern 305 may be exposed again.

In example embodiments, the spacer 440 may include, e.g., undoped amorphous silicon or undoped polysilicon. When the spacer 440 includes undoped amorphous silicon, the undoped amorphous silicon may be crystallized during subsequent deposition processes.

Portions of the support layer 300 and the support pattern 305 not covered by the spacer 440 and a portion of the sacrificial layer structure 290 thereunder may be removed to enlarge the second opening 430 downwardly. Thus, the second opening 430 may expose the upper surface of the CSP 240, and further extend through the upper portion of the CSP 240.

When the sacrificial layer structure 290 is partially removed, the sidewall of the second opening 430 may be covered by the spacer 440, which may include a material different from that of the sacrificial layer structure 290, so that the insulation patterns 315 and the fourth sacrificial patterns 325 included in the mold may not be removed.

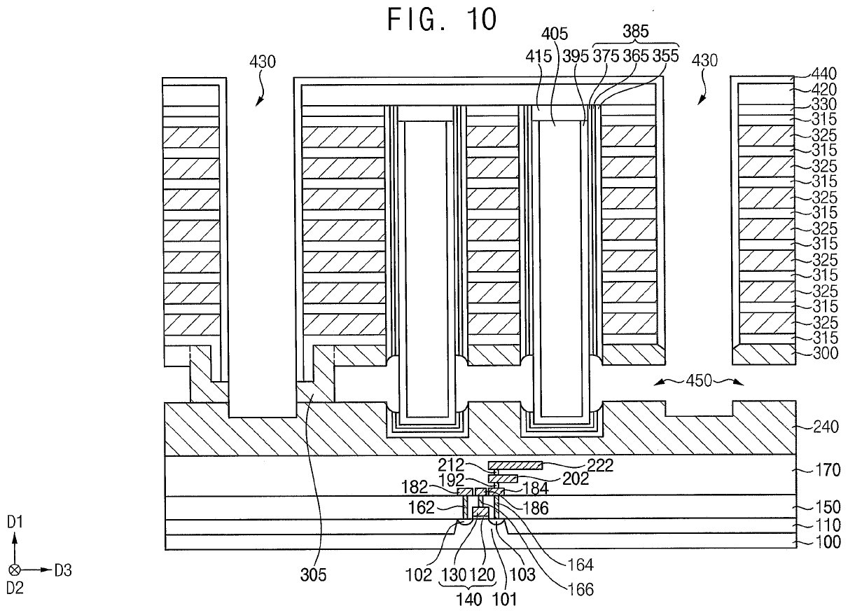

Referring to FIG. 10, the sacrificial layer structure 290 exposed by the second opening 430 may be removed to form a first gap 450 exposing a lower outer sidewall of the charge storage structure 385, and a portion of the charge storage structure 385 exposed by the first gap 450 may be further removed to expose a lower outer sidewall of the channel 395.

The sacrificial layer structure 290 and the charge storage structure 385 may be removed by a wet etching process using, e.g., hydrofluoric acid or phosphoric acid. When the first gap 450 is formed, the support layer 300, the support pattern 305, the channel 395 and the filling pattern 405 may support the mold so as not to collapse.

As the first gap 450 is formed, the charge storage structure 385 may be divided into an upper portion extending through the mold to cover almost an entire outer sidewall of the channel 395, and a lower portion covering a lower surface of the channel 395 on the CSP 240.

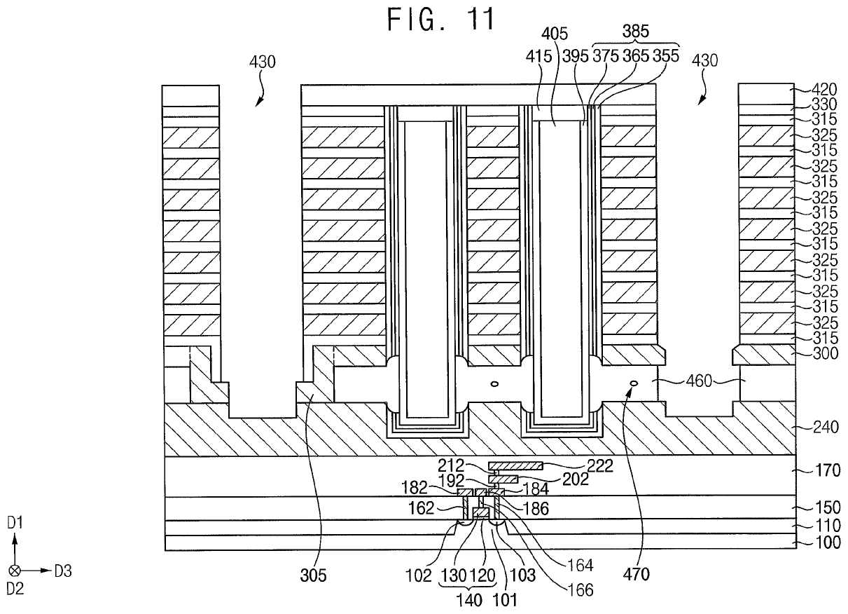

Referring to FIG. 11, after removing the spacer 440, a channel connection pattern 460 may be formed to fill the first gap 450.

The channel connection pattern 460 may be formed by forming a channel connection layer on the CSP 240 and the fourth insulating interlayer 420 to fill the second opening 430 and the first gap 450, and performing, e.g., an etch back process on the channel connection layer. The channel connection layer may include, e.g., amorphous silicon doped with n-type impurities, and may be crystallized by heat generated by subsequent deposition processes so as to include polysilicon doped with n-type impurities. As the channel connection pattern 460 is formed, the channels 395 between neighboring ones of the second openings 430 in the third direction D3 may be connected with each other to form a channel block.

An air gap 470 may be formed in the channel connection pattern 460.

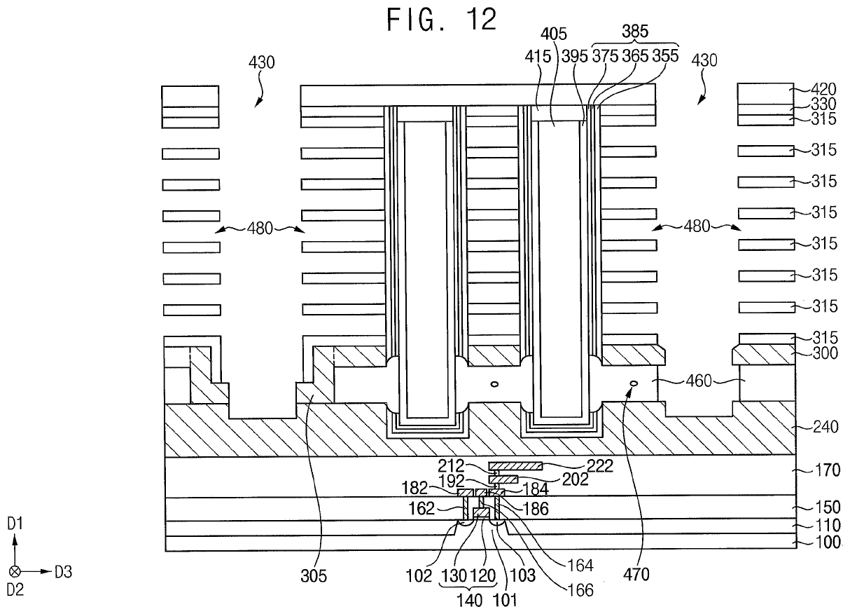

Referring to FIG. 12, the fourth sacrificial patterns 325 may be removed to form a second gap 480 exposing an outer sidewall of the charge storage structure 385. The fourth sacrificial patterns 325 may be removed by a wet etching process using e.g., phosphoric acid or hydrofluoric acid.

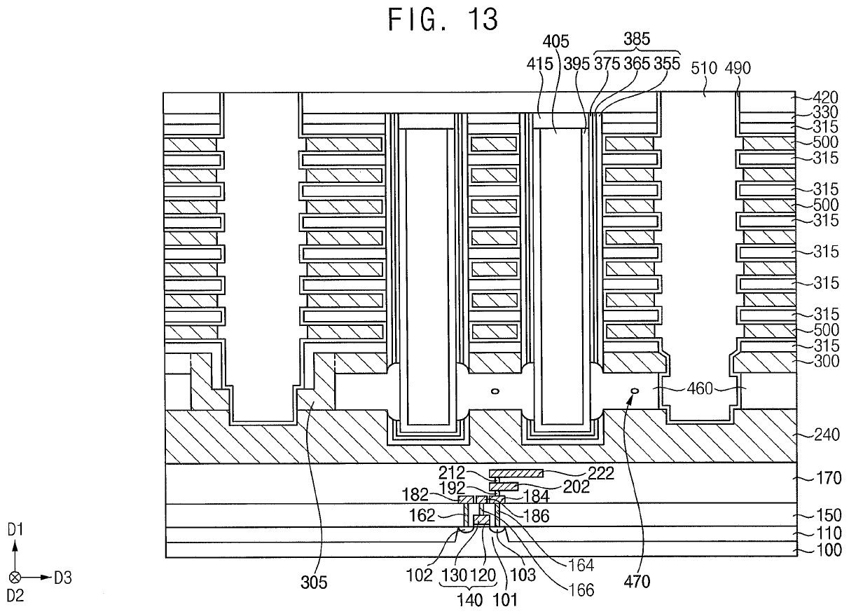

Referring to FIG. 13, a second blocking layer may be formed on the exposed outer sidewall of the charge storage structure 385, inner walls of the second gaps 480, surfaces of the insulation patterns 315, sidewalls of the support layer 300 and the support pattern 305, a sidewall of the channel connection pattern 460, the upper surface of the CSP 240, and the upper surface of the fourth insulating interlayer 420, and a gate electrode layer may be formed to fill the second gaps 480 and the second openings 430 on the second blocking layer. The gate electrode layer may include a gate barrier layer and a gate conductive layer sequentially stacked.

The second blocking layer may include, e.g., a metal oxide, the gate barrier layer may include a metal nitride, e.g., titanium nitride, tantalum nitride, tungsten nitride, etc., and the gate conductive layer may include a metal, e.g., tungsten, copper, etc.

The gate electrode layer may be partially removed to form a gate electrode 500 in each of the second gaps 480. In example embodiments, the gate electrode layer may be partially removed by a wet etching process.

In example embodiments, the gate electrode 500 may extend in the second direction D2, and a plurality of gate electrodes 500 may be formed in the first direction D1, which may form (e.g., define, establish, etc.) a gate electrode structure that extends in the second direction D2. Additionally, a plurality of gate electrode structures may be formed in the third direction D3, and may be spaced apart from each other (e.g., isolated from direct contact with each other) by the second opening 430.

In example embodiments, each of the gate electrodes 500 included in the gate electrode structure may serve as one of a ground selection line (GSL), a word line, or a string selection line (SSL) according to its position. In some example embodiments, a lowermost one of the gate electrodes 500 may serve as the GSL, an uppermost one and a second one from above of the gate electrodes 500 may serve as the SSLs, respectively, and a plurality of gate electrodes 500 between the GSL and the SSL may serve as the word lines, respectively. In some example embodiments, one or a plurality of gate electrodes 500 may be further formed under the GSL or over the SSL, which may serve as a gate induced drain leakage (GIDL) for body erasing using GIDL phenomenon. Some of the gate electrodes 500 serving as the word lines may be dummy word lines.

A division layer may be formed on the second blocking layer to fill the second opening 430, and the division layer and the second blocking layer may be planarized until the upper surface of the fourth insulating interlayer 420 is exposed. Thus, the second blocking layer may be transformed into a second blocking pattern 490, and the division layer may be transformed into a division pattern 510 filling the second opening 430 and extending in the second direction D2.

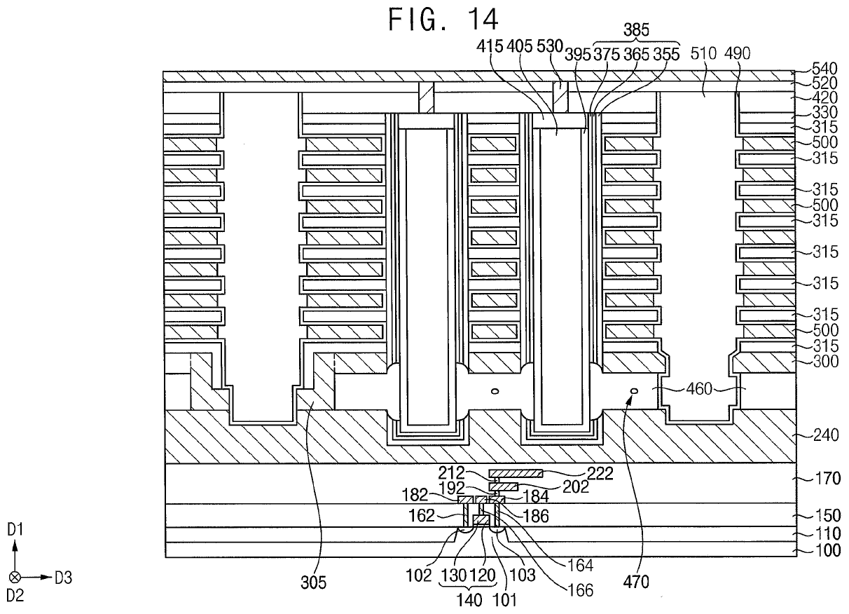

Referring to FIG. 14, a fifth insulating interlayer 520 may be formed on the fourth insulating interlayer 420, the division pattern 510 and the second blocking pattern 490, and a contact plug 530 may be formed through the fourth and fifth insulating interlayers 420 and 520 to contact an upper surface of the pad 415.

A bit line 540 may be formed on an upper surface of the contact plug 530. In example embodiments, the bit line 540 may extend in the third direction D3, and a plurality of bit lines 540 may be spaced apart from each other (e.g., isolated from direct contact with each other) in the second direction D2.

Upper contact plugs contacting upper surfaces of the gate electrodes 500, respectively, and upper wirings for applying electrical signals thereto may be further formed so that the semiconductor device may be manufactured.

If the insulation layer 310 includes, e.g., silicon oxide, a thickness in the first direction D1 of the insulation layer 310 may be equal to or greater than a thickness in the first direction D1 of the fourth sacrificial layer 320 replaced with the gate electrode 500. That is, the insulation layer 310 formed between the gate electrodes 500 may require a thickness in the first direction D1 to a certain degree in order to suppress an interference phenomenon between the gate electrodes 500, and as the dielectric constant of the insulating material included in the insulation layer 310 increases, the thickness in the first direction D1 of the insulation layer 310 has to increase. Thus, a height in the first direction D1 of an upper surface of the mold including the insulation layers 310 and the fourth sacrificial layers 320 alternately stacked in the first direction D1 may increase, and thus the mold may be bent and/or collapse in a manufacturing process of the semiconductor device.

However, in example embodiments, the insulation layer 310 may include, e.g., boron nitride, which may have a dielectric constant less than that of silicon oxide. Accordingly, even if the thickness in the first direction D1 of the insulation layer 310 is small, the interference phenomenon between the gate electrodes 500 may be effectively suppressed. The insulation layer 310 may have a thickness in the first direction D1 less than that of the fourth sacrificial layer 320. Thus, the height in the first direction D1 of an upper surface of the mold may decrease, and bending and/or collapse of the mold may be reduced or prevented in the manufacturing process of the semiconductor device. Additionally, the semiconductor device may have an improved degree of integration.

The semiconductor device manufactured by the above processes may have following structural characteristics.

The semiconductor device may include the lower circuit pattern on the substrate 100, the CSP 240 on the lower circuit pattern, the insulation patterns 315 spaced apart from each other (e.g., isolated from direct contact with each other) on the CSP 240 (and thus on the substrate 100) in the first direction D1 that is perpendicular or substantially perpendicular to the upper surface of the substrate 100 and each extending in the second direction D2 that is parallel or substantially parallel to the upper surface of the substrate 100, the gate electrodes 500 spaced apart from each other (e.g., isolated from direct contact with each other) in the first direction D1 and extending between the insulation patterns 315 in the second direction D2, where each gate electrode 500 extends in the second direction D2 between neighboring (e.g., adjacent) insulation patterns 315 of the adjacent insulation patterns 315, and the memory channel structure extending through the insulation patterns 315 and the gate electrodes 500 on the CSP 240 and connected to the CSP 240. In some example embodiments, the gate electrodes 500 may be spaced apart from each other (e.g., isolated from direct contact with each other) on the substrate 100 in the first direction D1 and may each extend in the second direction D2, and the insulation patterns 315 may each be between neighboring gate electrodes 500 (e.g., between adjacent gate electrodes 500). Additionally, the semiconductor device may further include the support layer 300, support pattern 305, the channel connection pattern 460, the second blocking pattern 490, the division pattern 510, the contact plug 530, the bit line 540, and the first to fifth insulating interlayers 150, 170, 330, 420 and 520.

In example embodiments, the insulation pattern 315 (e.g., each insulation pattern 315) may include, e.g., boron nitride, which may have a dielectric constant less than that of silicon oxide (e.g., less than a dielectric constant of silicon oxide. In some example embodiments, thickness ratio in the first direction D1 of the insulation pattern 315 (e.g., of each insulation pattern 315) to the gate electrode 500 (e.g., to each gate electrode 500) may be equal to or less than about 90%. In some example embodiments, a dielectric constant of each insulation pattern 315 may be less than about 3.3. In some example embodiments, the insulation pattern 315 (e.g., each insulation pattern 315) may include amorphous boron nitride, and a thickness ratio in the first direction D1 of the insulation pattern 315 (e.g., of each insulation pattern 315) to the gate electrode 500 may be equal to or more than about 50% and equal to or less than about 60%. A dielectric constant (k) of the insulation pattern 315 (e.g., each insulation pattern 315) may be less than about 1.8 (e.g., greater than 0 and less than about 1.8, greater than about 0.001 and less than about 1.8, etc.). In other example embodiments, the insulation pattern 315 (e.g., each insulation pattern 315) may include amorphous boron nitride and crystalline boron nitride, and a thickness ratio in the first direction D1 of the insulation pattern 315 (e.g., of each insulation pattern 315) to the gate electrode 500 (e.g., to each of the gate electrodes 500) may be more than about 60% and equal to or less than about 80%. A dielectric constant (k) of the insulation pattern 315 (e.g., each insulation pattern 315) may be equal to or more than about 1.8 and less than about 3. In other example embodiments, the insulation pattern 315 (e.g., each insulation pattern 315) may include crystalline boron nitride, and a thickness ratio in the first direction D1 of the insulation pattern 315 (e.g., of each insulation pattern 315) to the gate electrode 500 (e.g., to each gate electrode 500) may be more than about 80% and equal to or less than about 90%. A dielectric constant (k) of the insulation pattern 315 (e.g., each insulation pattern 315) may be equal to or more than about 3 and less than about 3.3.

In example embodiments, the gate electrodes 500 may form (e.g., define, establish, etc.) the gate electrode structure extending in the second direction D2. A plurality of the gate electrode structures may be formed along the third direction D3, and the division pattern 510 may be formed between the gate electrode structures to cause the gate electrode structures to be spaced apart from each other (e.g., isolated from direct contact with each other). the gate electrodes 500 may form (e.g., define, establish, etc.) the gate electrode structure that is one of the plurality of gate electrode structures that are disposed (e.g., arranged) in the third direction D3, which may be parallel or substantially parallel to the upper surface of the substrate 100 and may cross the second direction D2.

In example embodiments, the memory channel structure may include the channel 395 extending in the first direction D1 through the insulation patterns 315 and the gate electrodes 500 on the substrate 100, and the charge storage structure 385 surrounding the outer sidewall of the channel 395 and extending through the insulation patterns 315 and the gate electrodes 500.

In example embodiments, the division pattern 510 may contact sidewalls of the insulation patterns 315. For example, the division pattern 510 may contact one or more sidewalls of some or all of the insulation patterns 315. For example, the division pattern 510 may contact at least one sidewall of each of the insulation patterns 315.

As described herein, any devices, systems, modules, units, controllers, circuits, and/or portions thereof according to any of the example embodiments (including, without limitation, the electronic system 1000, semiconductor device 1100, controller 1200, decoder circuit 1110, page buffer 1120, logic circuit 1130, processor 1210, NAND controller 1220, electronic system 2000, controller 2002, semiconductor package 2003, DRAM device 2004, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, units, controllers, circuits, and/or portions thereof according to any of the example embodiments, and/or any portions thereof.

While example embodiments have been particularly shown and described, it will be understood by one of ordinary skill in the art that variations in form and detail may be made therein without departing from the spirit and scope of the claims.

What is claimed is:

1. A semiconductor device, comprising:
insulation patterns spaced apart from each other on a substrate in a first direction that is perpendicular to an upper surface of the substrate, each insulation pattern of the insulation patterns extending in a second direction that is substantially parallel to the upper surface of the substrate, wherein each insulation pattern of the insulation patterns includes boron nitride (BN);
gate electrodes spaced apart from each other in the first direction, each gate electrode of the gate electrodes extending in the second direction between neighboring insulation patterns of the insulation patterns; and
a channel extending in the first direction through the insulation patterns and the gate electrodes on the substrate.

2. The semiconductor device of claim 1, wherein each insulation pattern of the insulation patterns includes amorphous boron nitride and/or crystalline boron nitride.

3. The semiconductor device of claim 2, wherein
each insulation pattern of the insulation patterns includes amorphous boron nitride, and
a thickness ratio in the first direction of each insulation pattern of the insulation patterns to each of the gate electrodes is equal to or more than about 50% and equal to or less than about 60%.

4. The semiconductor device of claim 3, wherein a dielectric constant (k) of each insulation pattern of the insulation patterns is less than about 1.8.

5. The semiconductor device of claim 2, wherein
each insulation pattern of the insulation patterns includes amorphous boron nitride and crystalline boron nitride, and
a thickness ratio in the first direction of each insulation pattern of the insulation patterns to each of the gate electrodes is more than about 60% and equal to or less than about 80%.

6. The semiconductor device of claim 5, wherein a dielectric constant (k) of each insulation pattern of the insulation patterns is equal to or more than about 1.8 and less than about 3.

7. The semiconductor device of claim 2, wherein
each insulation pattern of the insulation patterns includes crystalline boron nitride, and
a thickness ratio in the first direction of each insulation pattern of the insulation patterns to each of the gate electrodes is more than about 80% and equal to or less than about 90%.

8. The semiconductor device of claim 7, wherein a dielectric constant (k) of each insulation pattern of the insulation patterns is equal to or more than about 3 and less than about 3.3.

9. The semiconductor device of claim 1, wherein
the gate electrodes form a gate electrode structure extending in the second direction,
the gate electrode structure is one of a plurality of gate electrode structures arranged in a third direction that is substantially parallel to the upper surface of the substrate and crossing the second direction, and
a division pattern is between the plurality of gate electrode structures, the plurality of gate electrode structures being spaced apart from each other by the division pattern.

10. The semiconductor device of claim 9, wherein the division pattern contacts sidewalls of the insulation patterns.

11. The semiconductor device of claim 1, further comprising:
a charge storage structure surrounding an outer sidewall of the channel, the charge storage structure extending through the insulation patterns and the gate electrodes.

12. A semiconductor device, comprising:
gate electrodes spaced apart from each other on a substrate in a first direction that is substantially perpendicular to an upper surface of the substrate, each of the gate electrodes extending in a second direction that is parallel to the upper surface of the substrate;
insulation patterns that are each between neighboring gate electrodes of the gate electrodes, the insulation patterns including an insulating material having a dielectric constant less than a dielectric constant of silicon oxide; and
a channel extending in the first direction through the insulation patterns and the gate electrodes on the substrate,
wherein a thickness ratio in the first direction of each insulation pattern of the insulation patterns to each gate electrode of the gate electrodes is equal to or less than about 90%.

13. The semiconductor device of claim 12, wherein each insulation pattern of the insulation patterns includes boron nitride.

14. The semiconductor device of claim 13, wherein each insulation pattern of the insulation patterns has a dielectric constant of less than about 3.3.

15. The semiconductor device of claim 13, wherein each insulation pattern of the insulation patterns includes amorphous boron nitride and/or crystalline boron nitride.

16. A semiconductor device, comprising:
a lower circuit pattern on a substrate;
a common source plate (CSP) on the lower circuit pattern;
insulation patterns spaced apart from each other on the CSP in a first direction that is perpendicular to an upper surface of the substrate, each insulation pattern of the insulation patterns extending in a second direction that is substantially parallel to the upper surface of the substrate, wherein each insulation pattern of the insulation patterns includes boron nitride (BN);
gate electrodes spaced apart from each other in the first direction, each gate electrode of the gate electrodes extending in the second direction between neighboring insulation patterns of the insulation patterns; and
a memory channel structure extending through the insulation patterns and the gate electrodes on the CSP and connected to the CSP, the memory channel structure including
a channel extending in the first direction, and
a charge storage structure surrounding an outer sidewall of the channel.

17. The semiconductor device of claim 16, wherein each insulation pattern of the insulation patterns includes amorphous boron nitride and/or crystalline boron nitride.

18. The semiconductor device of claim 16, wherein
a thickness ratio in the first direction of each insulation pattern of the insulation patterns to each gate electrode of the gate electrodes is equal to or less than about 90%, and
a dielectric constant of each insulation pattern of the insulation patterns is less than about 3.3.

19. The semiconductor device of claim 16, wherein
the gate electrodes form a gate electrode structure extending in the second direction,
the gate electrode structure is one of a plurality of gate electrode structures arranged in a third direction that is substantially parallel to the upper surface of the substrate and crossing the second direction, and
a division pattern is between the plurality of gate electrode structures, the plurality of gate electrode structures being spaced apart from each other by the division pattern.

20. The semiconductor device of claim 19, wherein the division pattern contacts sidewalls of the insulation patterns.
